(19) United States
(12) Patent Application Publication
(10) Pub. No.: US 2025/0376081 A1
(43) Pub. Date: Dec. 11, 2025

(54) BATTERY TEMPERATURE MANAGEMENT SYSTEM AND METHOD

(71) Applicant: Toyota Material Handling, Inc., Columbus, IN (US)

(72) Inventors: Zhong Shi, Columbus, IN (US); Robert A. Newman, II, Columbus, IN (US); Yudong Hu, Columbus, IN (US); David Servin, Indianapolis, IN (US)

(21) Appl. No.: 19/230,539

(22) Filed: Jun. 6, 2025

Related U.S. Application Data
(60) Provisional application No. 63/657,428, filed on Jun. 7, 2024.

(51) Int. Cl. B60L 58/27; B60L 7/10; B60L 50/60; B60L 58/12; G01K 3/00; G01R 31/3842; H01M 10/625; H01M 10/633; H05B 1/02

(52) U.S. Cl. CPC B60L 58/27; B60L 7/10; B60L 50/60; B60L 58/12; G01K 3/005; G01R 31/3842; H01M 10/625; H01M 10/633; H05B 1/0236; B60L 2200/42; B60L 2240/429; B60L 2240/545

(57) ABSTRACT

A battery temperature management system is provided. The battery temperature management system includes a drive unit and a power unit. The drive unit includes a motor. The power unit includes a battery pack, a resistor, and a processor. The processor is configured to direct regenerative braking current from the motor to the resistor to heat the battery pack based on a motor current value and a battery pack state of charge value.

### CROSS-REFERENCE TO RELATED APPLICATION

This application claims priority to U.S. Provisional Patent Application No. 63/657,428, filed Jun. 7, 2024, the entire contents of which are incorporated herein by reference.

### BACKGROUND

Batteries are useful for providing power to vehicles. However, batteries are charged and operate most effectively within a specific temperature range (e.g., 10° C. to 20° C.).

In some instances, batteries can become overheated during charging. For example, if a battery electric vehicle is in high use and arrives at a charging station with a high battery temperature, charging the battery may overheat the battery. Similarly, in low-temperature environments, batteries can become too cold to operate or charge effectively. Additionally, low temperatures may degrade batteries and reduce their service life. Currently, conventional on-board heating and/or cooling systems offer limited capabilities to keep batteries in their proper operating temperature ranges.

Also, in battery electric vehicles, batteries at high states of charge and low temperatures have difficulty accepting pulse energy from regenerative braking systems. In such instances, a conventional friction braking system is used rather than a regenerative braking system. However, conventional friction braking systems require maintenance, have limited service life, create brake dust, and convert kinetic energy into wasted heat energy.

Accordingly, it would be useful to provide improved systems to manage battery temperature in battery electric vehicles.

### SUMMARY

Some embodiments provide a battery temperature management system including a drive unit including a motor, and a power unit including a battery pack, a resistor, and a processor. The processor is configured to direct regenerative braking current from the motor to the resistor to heat the battery pack based on a motor current value and a battery pack state of charge value.

In some embodiments, the processor selectively directs the regenerative braking current via a switch. The resistor can be configured as a resistive heating element such that when the regenerative braking current is delivered to the resistor, the battery pack is heated. The resistor can be positioned substantially adjacent to the battery pack. The resistor can be positioned within the battery pack. The processor can be further configured to direct the regenerative braking current from the motor to the resistor to heat the battery pack based on a battery pack temperature value. The battery pack can include a temperature sensor in communication with the processor, and the processor can determine the battery pack temperature value based on signals from the temperature sensor.

In some embodiments, when the battery pack state of charge value exceeds a threshold state of charge value, the battery pack temperature value is below a threshold temperature value, and the motor current value is below zero, the processor directs the regenerative braking current to the resistor. When the battery pack temperature value exceeds a threshold temperature value, the processor can direct the regenerative braking current to the battery pack. The battery pack can include a charge sensor in communication with the processor, and the processor can determine the battery pack state of charge value based on signals from the charge sensor. A motor current sensor can be in electrical communication with the motor and the processor, and the processor can determine the motor current value based on signals from the motor current sensor. The resistor can be spaced apart from the battery pack such that heat escaping as waste heat does not substantially impact a temperature of the battery pack. When the battery pack state of charge value is below a threshold state of charge value, the processor can direct the regenerative braking current to the battery pack. One or more of the battery pack and the resistor can be in communication with a ground.

Some embodiments provide a battery temperature management system including a battery pack and a resistor in communication with a controller. The controller is configured to direct regenerative braking current from a motor to the resistor to warm the battery pack based on a motor current value and a battery pack state of charge value.

In some embodiments, the controller can include an onboard interface and can be programmable via the onboard interface. When the motor current value is negative and the battery pack state of charge value exceeds a threshold state of charge value, the controller can direct the regenerative braking current to the resistor. The resistor can be configured as a resistive heating element supported by the battery pack.

Some embodiments provide a method for operating a power unit including determining a motor current value of a motor, determining a battery state of charge value of a battery pack, and directing regenerative braking current from the motor to a resistor to heat the battery pack based on the motor current value and the battery state of charge value.

In some embodiments, the resistor is configured as a resistive heating element such that when the regenerative braking current is delivered to the resistor, the battery pack is heated.

Some embodiments provide a battery temperature management system including a battery pack including a housing, one or more battery modules within the housing, and a plurality of heating pads affixed to the housing, and a battery controller configured to variably activate the plurality of heating pads.

In some embodiments, each of the plurality of heating pads is variably activated based on one or both of a temperature value of the one or more battery modules or an ambient temperature. The housing can include a plurality of surfaces, each of the plurality of surfaces can define an area, and the plurality of heating pads can be sized and shaped to correspond with the areas of the plurality of surfaces. The battery controller can be configured to produce varying heat transfer gradients within the housing via the plurality of heating pads. The battery controller can be configured to power the plurality of heating pads when a temperature value inside the housing is below a temperature threshold value. The battery controller can be configured to turn off one or more of the plurality of heating pads when a temperature value inside the housing is above a temperature threshold value. The plurality of heating pads can include a flexible mat and a power adjuster.

Some embodiments provide a battery temperature management system including a charger, a heat exchanger in communication with the charger, and a battery pack connectable to the charger and the heat exchanger. The battery pack includes one or more battery modules and a processor configured to determine a temperature value of the one or more battery modules and request temperature conditioning fluid from the heat exchanger based on the temperature value of the one or more battery modules.

In some embodiments, the battery pack is connected to the heat exchanger via a first fluid line and a second fluid line. The battery pack can include a fluid plate, and the fluid plate can define an internal fluid passageway. The heat exchanger can be configured to circulate the temperature conditioning fluid through the battery pack. Each of the one or more battery modules can include a temperature sensor in communication with the processor. The heat exchanger can selectively heat or cool the battery pack via the temperature conditioning fluid. The heat exchanger can include one of a reversible heat pump or a resistive heater.

### BRIEF DESCRIPTION OF THE DRAWINGS

The accompanying drawings, which are incorporated in and form a part of this specification, illustrate embodiments of the invention and, together with the description, serve to explain the principles of embodiments of the invention:

FIG. 1 is a schematic view of a battery temperature management system according to the principles of this disclosure;

FIG. 2 is a side view of a battery electric vehicle of the first battery temperature management system of FIG. 1;

FIG. 3 is a schematic view of a battery pack of the battery electric vehicle of FIG. 2;

FIG. 4 is a schematic view of a fluid plate of the battery pack of FIG. 3;

FIG. 5 is a schematic view of a connector assembly of the battery electric vehicle of FIG. 2;

FIG. 6 is a schematic view of a heat exchanger of the first battery temperature management system of FIG. 1;

FIGS. 7A-7C are flow diagrams depicting a method for operating the system of FIG. 1 according to the principles of this disclosure;

FIG. 8 is a schematic view of a battery electric vehicle with a power unit according to the principles of this disclosure;

FIG. 9 is a schematic view of a controller of the power unit of FIG. 8;

FIG. 10 is a flow diagram depicting a method for operating the power unit of FIG. 8 according to the principles of this disclosure;

FIG. 11 is a back right isometric view of another battery temperature management system according to the principles of this disclosure;

FIG. 12 is a front right isometric view of the battery temperature management system of FIG. 11;

FIG. 13 is a bottom view of the battery temperature management system of FIG. 11; and

FIG. 14 is an isometric view of an exemplary heating pad for the battery temperature management system of FIG. 11.

### DETAILED DESCRIPTION

The following discussion is presented to enable a person skilled in the art to make and use embodiments of the invention. Various modifications to the illustrated embodiments will be readily apparent to those skilled in the art, and the generic principles herein can be applied to other embodiments and applications without departing from embodiments of the invention. Thus, embodiments of the invention are not intended to be limited to the embodiments shown but are to be accorded the widest scope consistent with the principles and features disclosed herein. The figures, which are not necessarily to scale, depict selected embodiments and are not intended to limit the scope of embodiments of the invention. Skilled artisans will recognize that the examples provided herein have many useful alternatives that fall within the scope of embodiments of the invention.

It is to be understood that the phraseology and terminology used herein are for the purpose of description and should not be regarded as limiting. For example, the use of “including,” “comprising,” or “having” and variations thereof herein is meant to encompass the items listed thereafter and equivalents thereof, as well as additional items. As used herein, unless otherwise specified or limited, the terms “mounted,” “connected,” “supported,” and “coupled” and variations thereof are used broadly and encompass both direct and indirect mountings, connections, supports, and couplings. Further, unless otherwise specified or limited, “connected” and “coupled” are not restricted to physical or mechanical connections or couplings.

For the purpose of defining and describing the present disclosure, it is noted that the term “processor” generally means a device that executes functions according to machine-readable instructions or that has been configured to execute functions in a manner analogous to machine-readable instructions, such as an integrated circuit, a microchip, a computer, a central processing unit, a graphics processing unit, field-programmable gate array (FPGA), an application-specific integrated circuit (ASIC), or any other computation device. Additionally, it is noted that the term “memory,” as used herein, generally means one or more apparatus capable of storing data or machine-readable instructions for later retrieval, such as, but not limited to, RAM, ROM, flash memory, hard drives, or combinations thereof.

As used herein, unless otherwise specified or limited, “at least one of A, B, and C,” and similar other phrases, are meant to indicate A, or B, or C, or any combination of A, B, and/or C. As such, this phrase, and similar other phrases can include single or multiple instances of A, B, and/or C, and, in the case that any of A, B, and/or C indicates a category of elements, single or multiple instances of any of the elements of the categories A, B, and/or C.

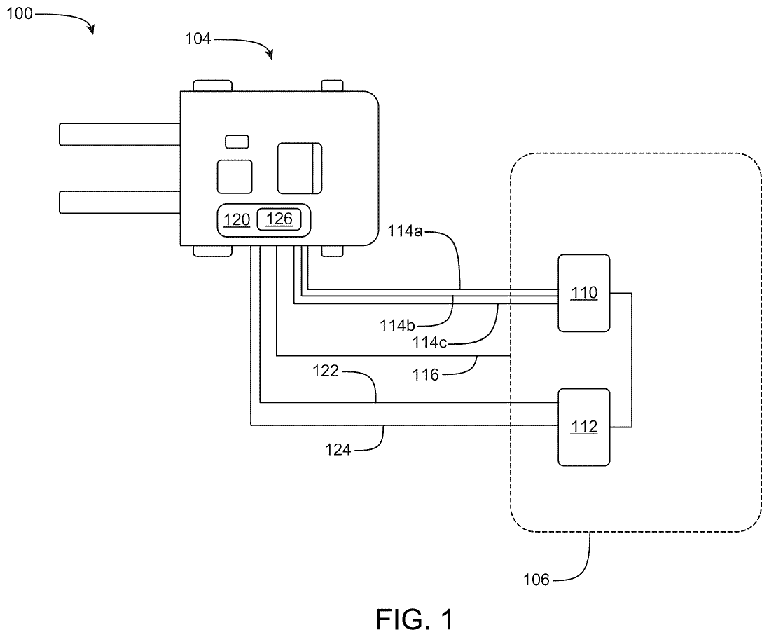

As explained above, it would be useful to provide improved systems to manage battery temperature. More particularly, improved systems are disclosed that (1) utilize high capacity off-board heating and cooling, (2) recover regenerative current for temperature management, and/or (3) variably modify the temperature of specific regions of a battery pack using heating elements. FIG. 1 illustrates a battery temperature management system 100 that provides off-board heating and cooling as well as charging of a battery electric vehicle 104. Here, the battery temperature management system 100 includes the battery electric vehicle 104 and a heat exchanging charging station 106, which includes a charger 110 and a heat exchanger 112. The battery electric vehicle 104 is depicted as a material handling vehicle but may be any type of battery electric vehicle (e.g., automobile, golf cart, motorcycle, etc.).

The heat exchanging charging station 106 can include a memory and a processor for executing instructions related to the function of the charger 110 and the heat exchanger 112. To provide coordinated functionality between the charger 110 and the heat exchanger 112, the charger 110 and the heat exchanger 112 are also in wired and/or wireless communication with one another. In some embodiments, the charger 110 is a high-amperage fast charger. Additionally, the heat exchanger 112 may include a chiller (e.g., a refrigeration system), a heater (e.g., a resistive heater), and a reversible heat pump, among other temperature control devices that utilize the circulation of a heat transfer fluid.

Referring still to FIG. 1, the battery electric vehicle 104 may be selectively connected to the charger 110 by a first electrical line 114a (e.g., positive), a second electrical line 114b (e.g., negative), and a third electrical line 114c (e.g., ground) for charging the battery pack 120. During charging, the charger 110 supplies electrical energy to the battery electric vehicle 104, which stores the electrical energy in a battery pack 120. The heat exchanger 112 may be connected to the battery electric vehicle 104 by a first fluid line 122 and a second fluid line 124. Further, the heat exchanger 112 may supply and circulate temperature-conditioned heat transfer fluid to heat and/or cool the battery pack 120.

The battery electric vehicle 104 may be selectively connected to the heat exchanging charging station 106 by communication lines 116 for the transfer of data, instructions, commands, information, and the like. In some embodiments, the communication lines 116 are provided in the form of CAN bus communication lines and can include a CAN high wire and a CAN low wire. Alternatively, or in addition, the communication lines 116 can be configured to provide other electronic communication methods known in the art. In some forms, the communication lines 116 also include a pilot line that helps identify when a proper connection between the battery pack 120 and the charger 110 is made. In some forms, multiple battery electric vehicles 104 can be selectively connected to the heat exchanging charging station 106 at the same time.

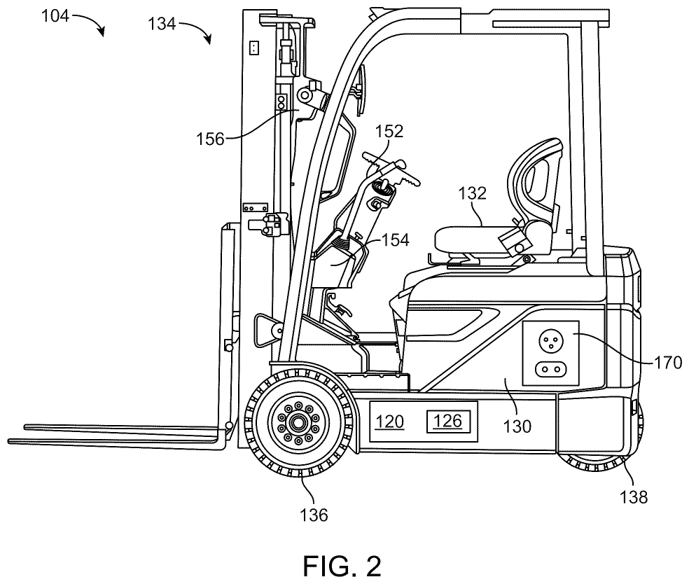

FIG. 2 illustrates the battery electric vehicle 104 in additional detail. For example, the battery electric vehicle 104 can comprise a vehicle body 130 having a driver's seat 132 associated with the body 130. A mast 134 can be provided in front of the driver's seat 132 for raising and lowering a lifting attachment configured to lift a load. The body 130 can further be connected to sets of wheels 136 and wheel 138 at a front portion and at a rear portion of the body 130, respectively. A control lever 152 can be provided near the driver's seat 132 for controlling the battery electric vehicle 104. For example, the control lever 152 can be used to shift the battery electric vehicle 104 into forward or backward movements. The control lever 152 can be coupled to a main controller 154, which includes a processor, a memory, and a display 156 onboard the body 130.

Referring further to FIG. 2, the battery electric vehicle 104 is powered by the battery pack 120, which is rechargeable. A battery controller 126 is coupled electrically, communicatively, or both with the display 156, the main controller 154, and other components of the battery electric vehicle 104. The battery controller 126 serves as the central gatekeeper for charging the battery pack 120 and delivering power from the battery pack 120 to the battery electric vehicle 104. For example, the battery controller 126 can be programmed to control battery charging provided by the charger 110 (shown in FIG. 1). The battery controller 126 also serves as the central gatekeeper for the heating and cooling of the battery pack 120 via the heat exchanger 112, which will be described in further detail below. The battery electric vehicle 104 further includes a connector assembly 170, which is supported by the body 130. The connector assembly 170 is externally accessible to a user (e.g., the operator of the battery electric vehicle 104) for connection to the heat exchanging charging station 106 (shown in FIG. 1).

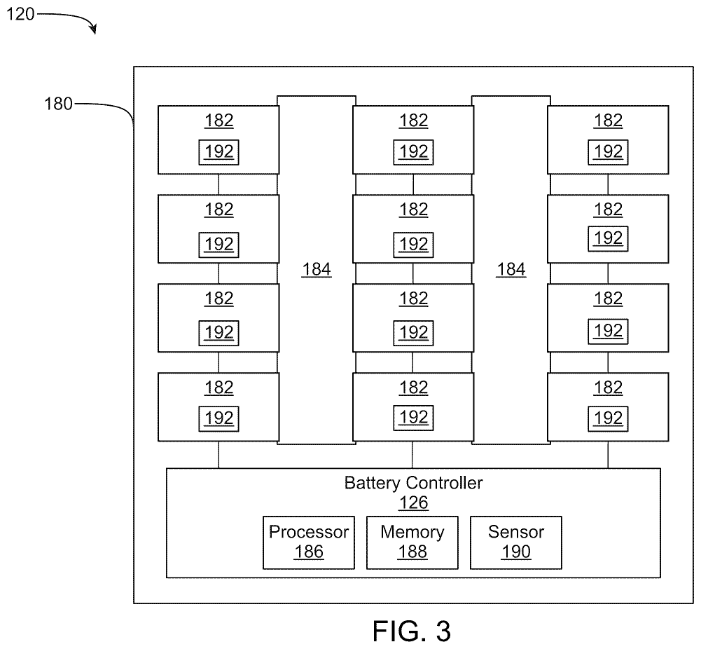

FIG. 3 illustrates the battery pack 120 of the battery electric vehicle 104 in additional detail. For example, the battery pack 120 includes the battery controller 126, a housing 180, a plurality of battery modules 182, and a plurality of fluid plates 184. Here, the battery controller 126 is coupled electrically, communicatively, or both with each of the battery modules 182. To manage the temperature of the battery pack 120 and the individual battery modules 182, the fluid plates 184 are positioned adjacent the battery modules 182, and in some embodiments, the fluid plates 184 physically contact one or more battery modules 182. Accordingly, the fluid plates 184 can transfer heat to and from the battery modules 182 via conduction, radiation, or both. In some forms, the housing 180 includes spacers, other structural plates, and other vibration dampening or cooling elements such as foam cushioning. The battery modules 182 can be provided in the form of lithium-ion batteries. The battery modules 182 can also be electrically coupled to one another to provide a nominal voltage value and a nominal capacity value. For example, in some forms, the battery modules are arranged and electrically coupled to provide a nominal voltage value of 36V or 48V. In some forms, the battery modules 182 are electrically coupled to provide a nominal capacity value of one of 540 Ahr or 720 Ahr. Thus, the battery pack 120 is modular and can be provided with different arrangements and quantities of the battery modules 182.

In particular, the battery controller 126 includes a processor 186, a memory 188, and one or more sensors 190 configured to determine current draw values, voltage values, temperature values, and state of charge values. In some embodiments, the battery modules 182 themselves can include one or more sensors 192 configured to sense one or more parameters (e.g., state of charge, temperature level, and the like) of the battery modules 182 or the battery pack 120. For example, the battery controller 126 and/or the battery modules 182 can include one or more of a temperature sensor, a voltage sensor, and/or a current sensor. In some forms, the battery modules 182 communicate sensed parameters to the battery controller 126 for aggregation, storage, or communicating the sensed parameters to other system components.

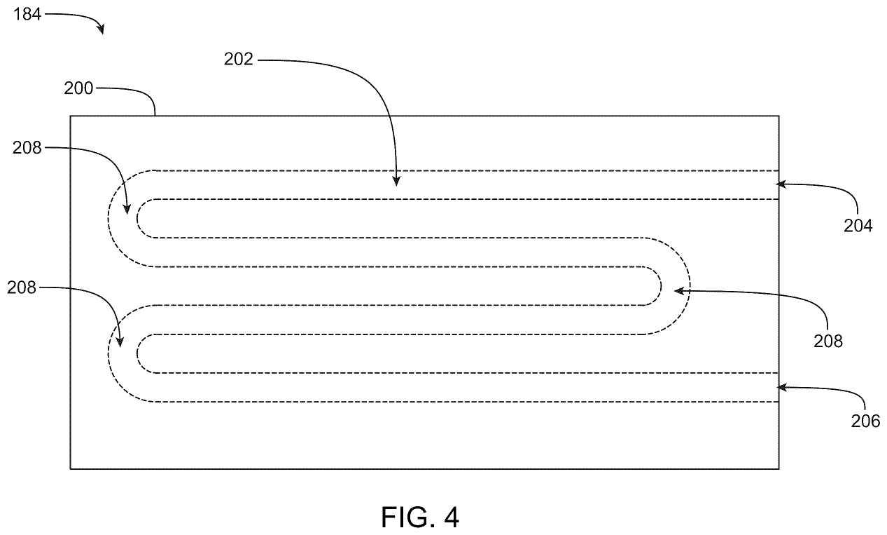

FIG. 4 illustrates the fluid plate 184 in additional detail. The fluid plate 184 includes a heat-exchanging body 200 that defines an internal passageway 202 (shown in phantom), and the internal passageway 202 includes an inlet 204, an outlet 206, and a plurality of bends 208. Thus, the internal passageway 202 defines an undulating, circuitous, zigzag, meandering, and/or serpentine flow path to provide a flow of heat transfer fluid through the heat-exchanging body 200. It should be understood that the internal passageway 202 can be provided in any number of geometric designs such that heat transfer fluid can be effectively circulated within the heat-exchanging body 200 of the fluid plate 184.

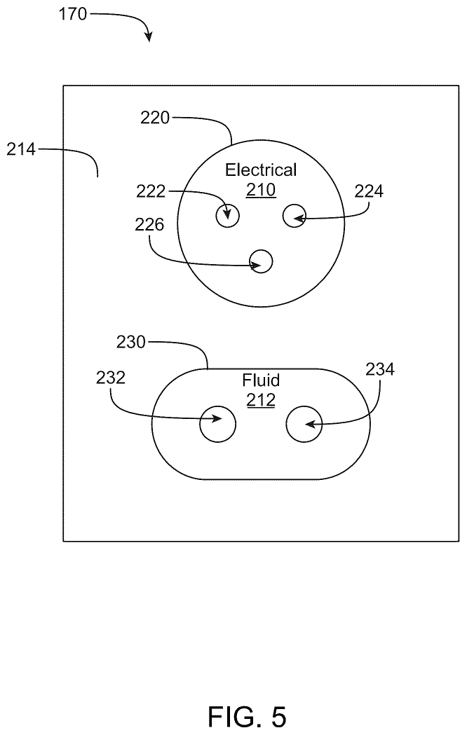

FIG. 5 illustrates the connector assembly 170 in additional detail. For example, the connector assembly 170 includes an electrical connector 210 and a fluid connector 212 supported by a mounting plate 214. The electrical connector 210 includes a first housing 220 that defines a first electrical port 222 (e.g., positive), a second electrical port 224 (e.g., negative), and a third electrical port 226 (e.g., ground). The first electrical port 222, the second electrical port 224, and the third electrical port 226 are configured to matingly receive the first electrical line 114a, the second electrical line 114b, and the third electrical line 114c (shown in FIG. 1), respectively, in a selectively attachable manner, e.g., via a standardized plug such as NEMA 14-30, IEC 60309, SAE J1772-Type 1, IEC 62196-Type 2, among others. The fluid connector 212 includes a second housing 230 that defines a first fluid port 232 and a second fluid port 234. The first fluid port 232 and the second fluid port 234 are configured to matingly receive the first fluid line 122 and the second fluid line 124 (shown in FIG. 1), respectively, in a selectively attachable manner, e.g., standard quick connect hose fittings. The first housing 220 can also include connection points (not shown) such as a CAN high port, a CAN low port, and a pilot line port to receive communications from the communication lines 116. Alternatively, or in addition, the first housing 220 can include connection points (not shown) to receive communication lines 116 configured to provide other electronic communication methods known in the art.

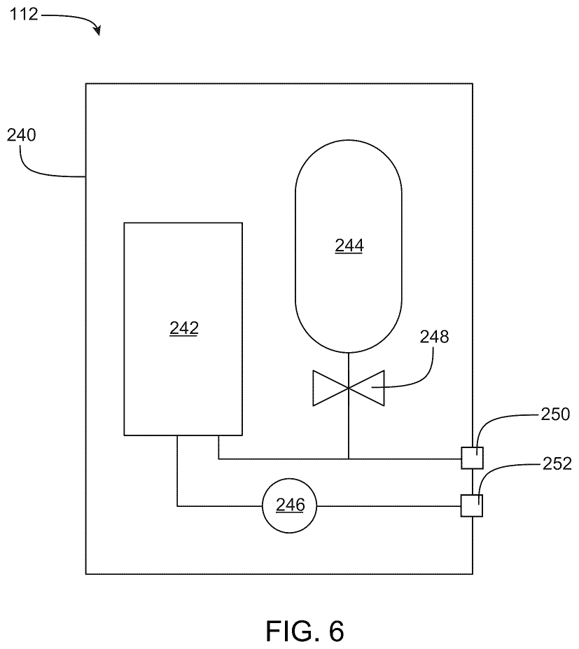

Referring next to FIG. 6, in some embodiments, the heat exchanger 112 includes a housing 240 that contains a heat pump 242, a pressure vessel 244, a pump 246, a deaeration valve 248, an inlet port 250, and an outlet port 252, which are all fluidly coupled to one another. The inlet port 250 directs heat transfer fluid to the pump 246, which pumps heat transfer fluid to the heat pump 242. The heat pump 242 then directs heat transfer fluid to the outlet port 252 and the pressure vessel 244. The deaeration valve 248 is fluidly coupled between the pressure vessel 244, the outlet port 252, and heat pump 242 to vent trapped bubbles and dissolved gases from the heat transfer fluid moving through the heat exchanger 112 into the pressure vessel 244. In some forms, the heat pump 242 is a reversible heat pump that cools or heats the heat transfer fluid. In some forms, the heat exchanger 112 includes a resistive heater (not shown). In operation, the outlet port 252 can provide heat transfer fluid to the first fluid line 122, and the inlet port 250 can receive heat transfer fluid from the second fluid line 124 (see FIG. 1) to provide temperature conditioned heat transfer fluid to the fluid plates 184 (see FIG. 3).

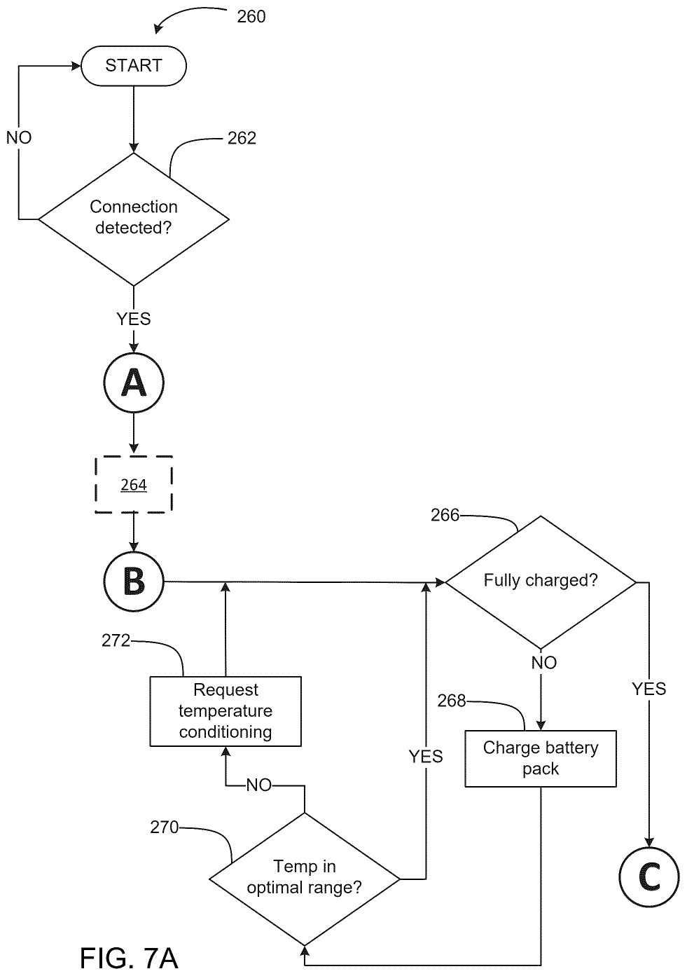

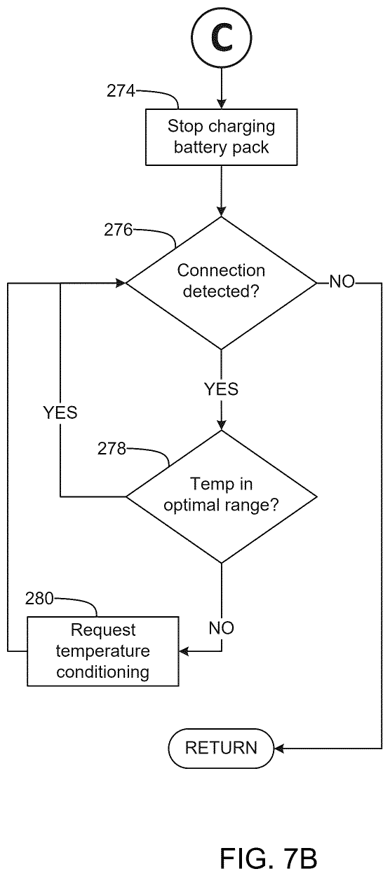

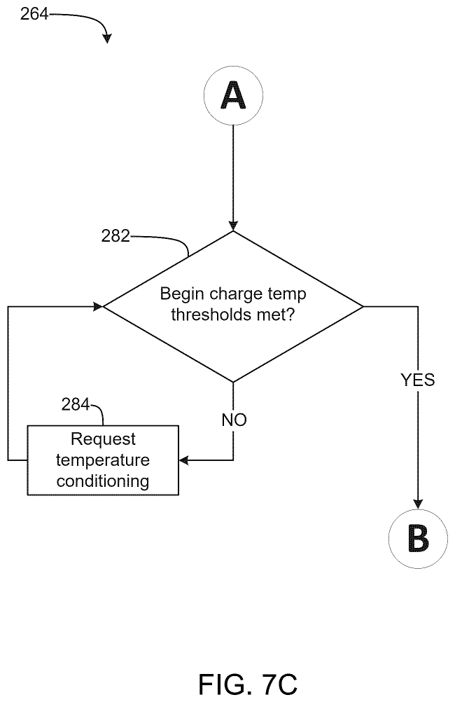

FIGS. 7A-7C illustrate a method 260 for operating the heat exchanging charging station 106 via the battery controller 126. Generally speaking, the battery controller 126 communicates with the heat exchanging charging station 106 via the communication lines 116 to control the charging of battery pack 120 and to control the circulation of heat transfer fluid through the fluid plates 184. More particularly, the method 260 starts at step 262, where the battery controller 126 and/or the heat exchanging charging station 106 determines whether the battery electric vehicle 104 and the heat exchanging charging station 106 are properly connected. For example, the battery controller 126 and/or the heat exchanging charging station 106 can determine that the first, second, and third electrical lines 114a, 114b, 114c, the communication lines 116, and the first and second fluid lines 122, 124 are properly connected between the battery pack 120 and the heat exchanging charging station 106. In some forms, the connection confirmation is communicated using a pilot line as mentioned above. If, at step 262, the battery controller 126 determines that the battery electric vehicle 104 has been properly connected to the heat exchanging charging station 106, the method 260 continues forward. However, if, at step 262, the battery controller 126 determines that the battery electric vehicle 104 has not been properly connected to the heat exchanging charging station 106, the method 260 goes back to the start and continues to await confirmation that a proper connection has been made.

After step 262, step 264 is provided in the form of a subroutine, which will be further described with respect to FIG. 7C. In some forms, the method 260 includes the subroutine 264. In some forms, however, the method 260 does not include the subroutine 264. The method 260 proceeds to step 266 next. At step 266, the battery controller 126 determines whether the battery pack 120 is substantially fully charged. The battery controller 126 determines the state of charge by way of the sensors 190 (see FIG. 3), which can be configured to collect voltage and current values of the battery pack 120. The battery controller 126 then compares the determined state of charge value to a state of charge threshold value to determine whether the battery pack 120 is substantially fully charged. In some forms, the threshold for a determination of fully charged includes an error value, such as an error value of +/−2%. Accordingly, if the state of charge is determined to be at 98%, the battery controller 126 will consider the battery pack 120 to be fully charged for the purposes of the method 260. If, at step 266, the battery controller 126 determines that the battery pack 120 is not fully charged, the method 260 proceeds to step 268. At step 268, the battery controller 126 requests charging from the charger 110.

Once charging has begun, the method 260 proceeds to step 270. At step 270, the battery controller 126 determines whether the battery pack 120 or any of the battery modules 182 are too hot or too cold. In response, the battery controller 126 can request heat transfer fluid from the heat exchanger 112 to modify the temperature of the battery pack 120 and the battery modules 182 accordingly in step 272. For example, the battery controller 126 can store one or more temperature threshold values in its memory 188 (see FIG. 3), and the battery controller 126 can compare sensed temperature values to the one or more temperature threshold values. The sensed temperature values can be determined by the sensors 190 of the battery controller 126 and/or the sensors 192 of the individual battery modules 182. In some embodiments, the temperature values that are ultimately compared to the temperature threshold values can be provided in the form of an average sensed temperature value over a period of time, a maximum or minimum sensed temperature value over a period of time, or simply a real-time sensed temperature value combined with a time interval, e.g., the real-time sensed temperature value exceeds the temperature threshold value for at least a predetermined amount of time. In some forms, the memory 188 stores one or more of a battery pack high temperature threshold value, a battery module high temperature threshold value, a battery pack low temperature threshold value, or a battery module low temperature threshold value. Accordingly, the memory 188 can store optimal temperature ranges within which the heat exchanging charging station 106 will keep the battery pack 120 during charging.

More specifically, at step 270, the battery controller 126 can determine whether one or more high temperature threshold values are exceeded. For example, in some forms, step 270 includes comparing a battery pack temperature value sensed by the sensors 190 to the battery pack high temperature threshold value. In some forms, step 270 includes comparing the battery module temperature values sensed by the sensors 192 to the battery module high temperature threshold value. If, at step 270, the battery controller 126 determines that the battery pack 120 or battery modules 182 are too hot, the method 260 proceeds to step 272. At step 272, the battery controller 126 will then request cooled heat transfer fluid from the heat exchanger 112, and the method 260 returns to step 266.

At step 270, the battery controller 126 also determines whether the battery pack 120 exceeds one or more of the low temperature threshold values. For example, in some forms, step 270 includes comparing battery pack temperature values sensed by the sensors 190 to the battery pack low temperature value. In some forms, step 270 includes comparing battery module temperature values sensed by the sensors 192 to the battery module low temperature threshold value. If, at step 270, the battery controller 126 determines that the battery pack 120 or the battery modules 182 are too cold, the method 260 proceeds to step 272. At step 272, the battery controller 126 will then request heated heat transfer fluid from the heat exchanger 112, and the method 260 returns to step 266.

Alternatively, if the battery controller 126 determines that the battery pack 120 and/or the battery modules 182 are within the optimal temperature range for charging, the method 260 moves from step 270 to step 266 without requesting any heat transfer fluid. Once the battery controller 126 has determined that the battery pack 120 is sufficiently charged in step 266, the method 260 moves on to step 274 (see FIG. 7B), where the battery controller 126 instructs the charger 110 to stop charging the battery pack 120. In some instances, the battery electric vehicle 104 is connected to the heat exchanging charging station 106 for opportunity charging or when the battery pack 120 is already mostly charged. In some other instances, the battery pack 120 is already fully charged when the battery electric vehicle 104 is connected to the heat exchanging charging station 106. In some other instances, the battery electric vehicle 104 will remain idle and unused for numerous hours after charging is complete, but the battery electric vehicle 104 is also still connected to the heat exchanging charging station 106. In all of these instances, among others, the battery pack 120 may need temperature conditioning after it has been substantially fully charged but the battery electric vehicle 104 is still connected to the heat exchanging charging station 106.

Accordingly, after step 274, when the battery controller 126 has determined that the battery pack 120 is fully charged and has stopped charging the battery pack 120, the battery controller 126 will determine whether the battery electric vehicle 104 is still connected to the heat exchanging charging station 106. If it is, the battery controller 126 will determine whether the battery pack 120 and/or the battery modules 182 are within an optimal temperature range in step 278. If the battery pack 120 and/or the battery modules 182 are not within the optimal temperature range, the battery controller 126 will request temperature conditioning from the heat exchanging charging station 106 in step 280. Steps 278 and 280 function similar to steps 270 and 272 (see FIG. 7A), respectively, and the discussion above regarding temperature control in steps 270 and 272 is incorporated by reference here with respect to steps 278 and 280. If the temperature of the battery pack 120 and/or the battery modules 182 are within the optimal temperature range, the battery controller 126 will continue to check for a connection between the battery electric vehicle 104 and the heat exchanging charging station 106 at step 276. In this way, while the battery electric vehicle 104 remains connected, the battery pack 120 will continue to be cooled or heated such that when an operator disconnects the battery electric vehicle 104 to begin driving it, the battery pack 120 will be at an optimal operating temperature. Once the battery controller 126 determines that the battery electric vehicle 104 has been disconnected from the heat exchanging charging station 106, the method 260 will end.

As detailed in FIG. 7C, the method 260 can optionally include a subroutine 264 that is executed between steps 262 and 266. The subroutine 264 is configured to prevent the battery pack 120 from charging if the starting temperature of the battery pack 120 is too high or too low. During steps 282 and 284 of the subroutine 264, the battery controller 126 determines whether the battery pack 120 or any of the battery modules 182 are too hot or too cold for optimal battery charging. In response, the battery controller 126 can request heat transfer fluid from the heat exchanger 112 to modify the temperature of the battery pack 120 and the battery modules 182 accordingly. For example, the battery controller 126 can store one or more charging temperature threshold values in its memory 188. Further, the battery controller 126 can compare sensed temperature values to the one or more charging temperature threshold values. The sensed temperature values can be determined by the sensors 190 of the battery controller 126 and/or the sensors 192 of the individual battery modules 182.

The temperature values that are compared to the charging temperature threshold values can be provided in the form of an average sensed temperature value over a period of time, a maximum or minimum sensed temperature value over a period of time, or simply a real-time sensed temperature value combined with a time interval, e.g., the real-time sensed temperature value exceeds the temperature threshold value for at least a predetermined amount of time. In some forms, the memory 188 stores one or more of a battery pack charging high temperature threshold value, a battery module charging high temperature threshold value, a battery pack charging low temperature threshold value, or a battery module charging low temperature threshold value. Accordingly, the memory 188 can store optimal temperature ranges within which the heat exchanging charging station 106 will keep the battery pack 120 before charging is initiated.

More specifically, at step 282, the battery controller 126 can determine whether one or more charging high temperature threshold values are exceeded. For example, in some forms, step 282 includes comparing a battery pack temperature value sensed by the sensors 190 to the battery pack charging high temperature threshold value. In some forms, step 282 includes comparing the battery module temperature values sensed by the sensors 192 to the battery module charging high temperature threshold value. If, at step 282, the battery controller 126 determines that the battery pack 120 is too hot for effective/efficient charging, the method 260 proceeds to step 284. At step 284, the battery controller 126 requests cooled heat transfer fluid from the heat exchanger 112, and the method 260 returns to step 282.

At step 282, the battery controller 126 also determines whether the battery pack 120 exceeds one or more of the charging low temperature threshold values. For example, in some forms, step 282 includes comparing battery pack temperature values sensed by the sensors 190 to the battery pack charging low temperature value. In some forms, step 282 includes comparing battery module temperature values sensed by the sensors 192 to the battery module charging low temperature threshold value. If, at step 282, the battery controller 126 determines that the battery pack 120 is too cold for effective/efficient charging, the method 260 proceeds to step 284. At step 284, the battery controller 126 requests heated heat transfer fluid from the heat exchanger 112, and the method 260 returns to step 282.

Alternatively, if the battery controller 126 determines that the battery pack 120 and/or the battery modules 182 are within the optimal temperature range for charging, the method 260 moves from step 282 to step 266 (see FIG. 7A) without requesting any heat transfer fluid. Accordingly, the subroutine 264 is configured to prevent the battery pack 120 from charging if its starting temperature is too high or too low.

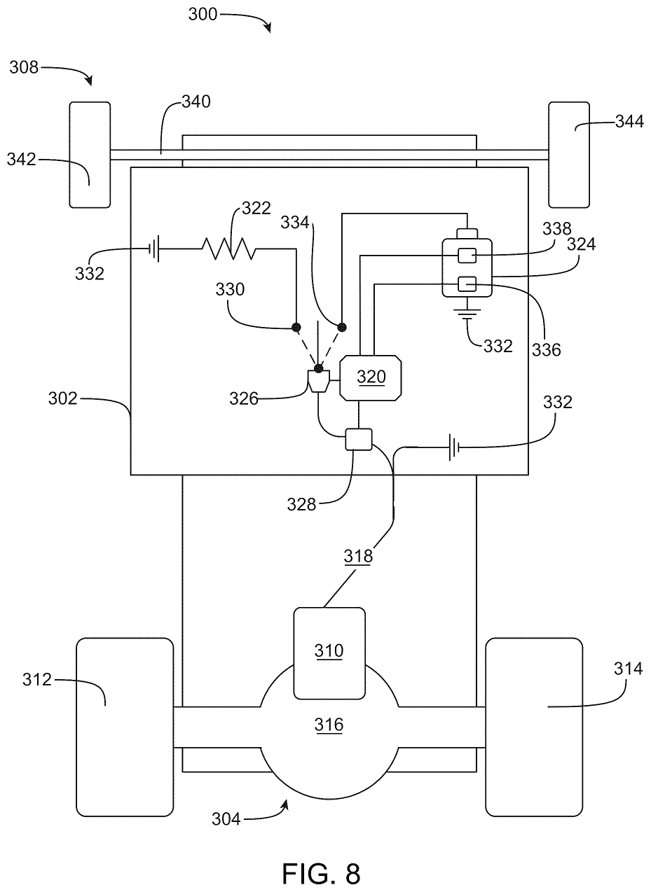

FIG. 8 illustrates a battery electric vehicle 300 with a power unit 302 for directing the flow of regenerative braking current based on various sensed conditions in order to heat a battery pack 324 of the battery electric vehicle 300 in a low temperature environment. In general, the power unit 302 helps prevent a battery overvoltage condition during low temperature operation of the battery electric vehicle 300. Here, the battery electric vehicle 300 comprises a drive unit 304, the power unit 302, and a wheel set 308. The drive unit 304 includes a traction motor 310 that rotates a first wheel 312 and a second wheel 314 via a drive linkage 316 when the traction motor 310 is provided with power. The traction motor 310 is in electrical communication with the power unit 302 via a power cable 318. Further, the wheel set 308 includes an axle 340 that connects a third wheel 342 to a fourth wheel 344.

The power unit 302 includes a controller 320, a resistor 322, the battery pack 324, a switch 326, and a motor current sensor 328. The resistor 322 is in electrical communication with a resistor terminal 330 and a ground 332. In some forms, the resistor 322 is configured as a resistive heating element that is positioned substantially adjacent to or within the battery pack 324 such that when current is delivered to the resistor 322, the battery pack 324 is heated. In some forms, when the resistor 322 receives current, the resistor 322 is positioned to allow the resulting heat to escape as waste heat. In some forms, the resistor 322 is spaced apart from the battery pack 324 such that the waste heat does not substantially impact a temperature of the battery pack 324. The battery pack 324 is in electrical communication with a battery terminal 334 and the ground 332. Further, the motor current sensor 328 is in electrical communication with the traction motor 310, the controller 320, the switch 326, and the ground 332. The battery pack 324 includes a temperature sensor 336 and a charge sensor 338, which are in electrical communication with the controller 320. The controller 320 is in electrical communication with the battery pack 324, the switch 326, and the motor current sensor 328.

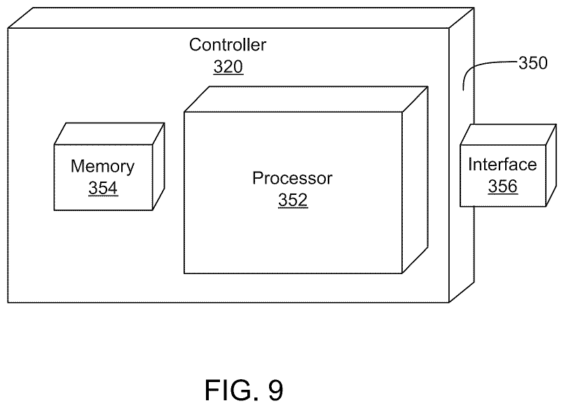

FIG. 9 illustrates a block diagram of the controller 320 in additional detail. For example, the controller 320 includes a housing 350 that contains a processor 352, a memory 354, and an interface 356. In some embodiments, the processor 352 and the memory 354 are retained within and thus protected by the housing 350. Additionally, the processor 352 is configured to retrieve information from the memory 354. The processor 352 is communicatively coupled with the memory 354 and the interface 356. The controller 320 may be initialized, set up, configured, and/or programmed via the interface 356.

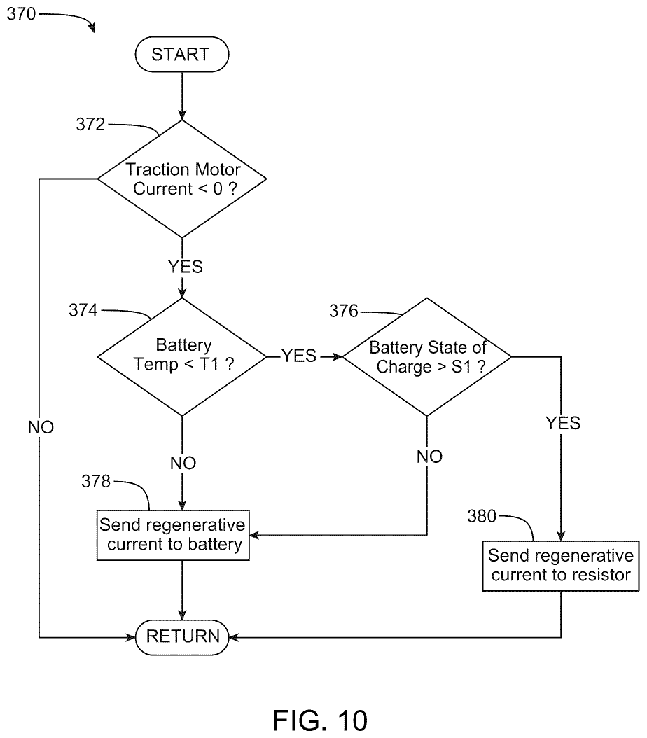

FIG. 10 illustrates a flow chart of a method 370 for directing the flow of regenerative braking current to either the battery pack 324 or to the resistor 322 based on the direction of current flow sensed by the motor sensor 328, the temperature of the battery pack 324 sensed by the temperature sensor 336, and the state of charge of the battery pack 324 determined by the charge sensor 338. In general, low temperatures cause the internal resistance of the battery pack 324 to increase and the battery pack 324 to become susceptible to an overvoltage condition. The method 370 addresses this concern, among others. The method 370 can be performed by the power unit 302 described above. The method 370 starts at step 372, where the controller 320 determines whether the traction motor 310 has a negative (i.e., less than zero) current, which indicates that the traction motor 310 is producing a regenerative braking current. If, at step 372, the controller 320 determines that the traction motor 310 is producing regenerative braking current, the method 370 proceeds to step 374. However, if, at step 372, the controller 320 determines that the traction motor 310 is not producing regenerative braking current, the method 370 returns to the beginning of step 372.

At step 374, the controller 320 determines whether the temperature of the battery pack 324 is below a threshold temperature value T₁. If, at step 374, the controller 320 determines that the temperature of the battery pack 324 sensed by the temperature sensor 336 is below the threshold temperature value T₁, the method 370 proceeds to step 376. However, if, at step 374, the controller 320 determines that the temperature of the battery pack 324 is not below the threshold temperature value T₁, the method 370 proceeds to step 378. At step 378, the controller 320 sends the regenerative braking current to the battery pack 324 by instructing the switch 326 to contact the battery terminal 334. Accordingly, the regenerative braking current is directed to recharge the battery pack 324. The method 370 then returns to step 372.

Referring next to step 376, the controller 320 determines whether the state of charge of the battery pack 324 is above a threshold state of charge value S₁. If, at step 376 the controller 320 determines that the state of charge of the battery pack 324 is above the threshold state of charge value S₁, the method 370 proceeds to step 380. However, if, at step 376, the controller 320 determines that the state of charge of the battery pack 324 is not above the threshold state of charge value S₁, the method 370 proceeds to step 378. At step 380, the controller 320 sends the regenerative braking current to the resistor 322. As described above, in some forms, step 380 will result in the resistor 322 heating the battery pack 324. The method 370 then returns to step 372. In some forms, regenerative braking current is sent to the resistor 322 (step 380) even if only one of the battery temperatures is below the threshold temperature value T₁ or the battery state of charge is below the threshold state of charge S₁. Accordingly, the power unit 302 and the method 370 work to prevent overcharging the battery pack 324 during low temperature operation.

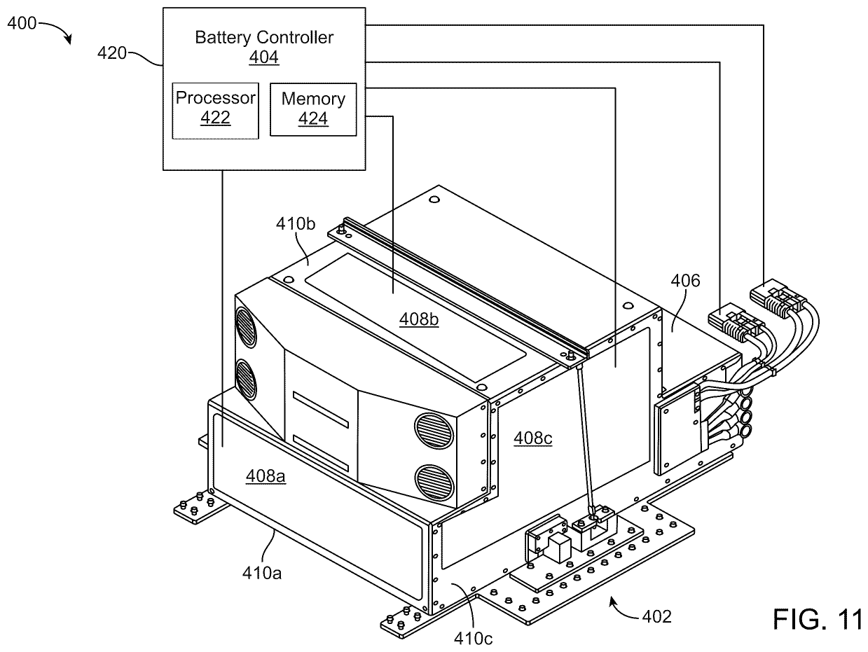

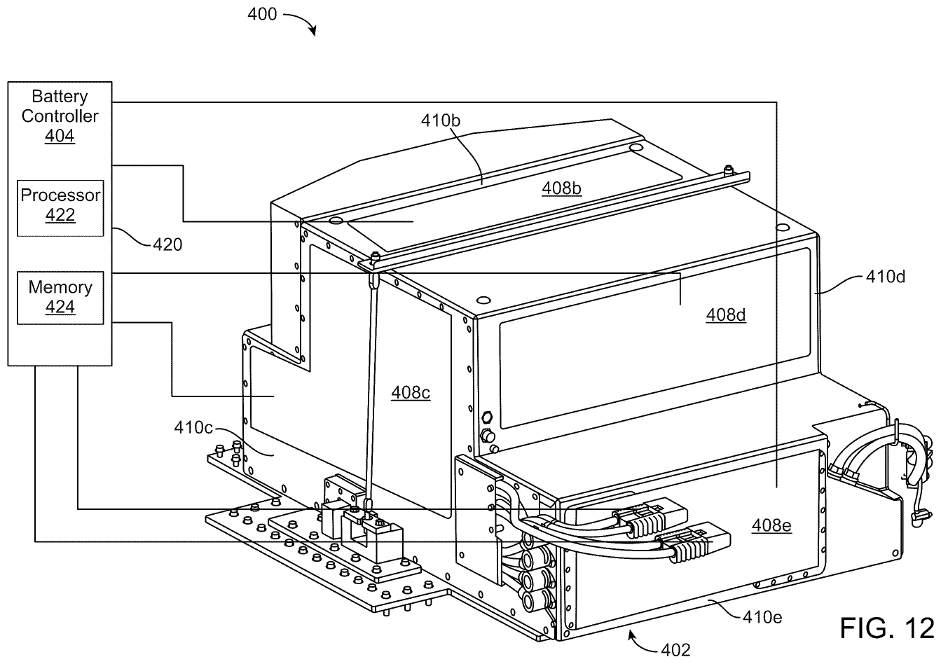

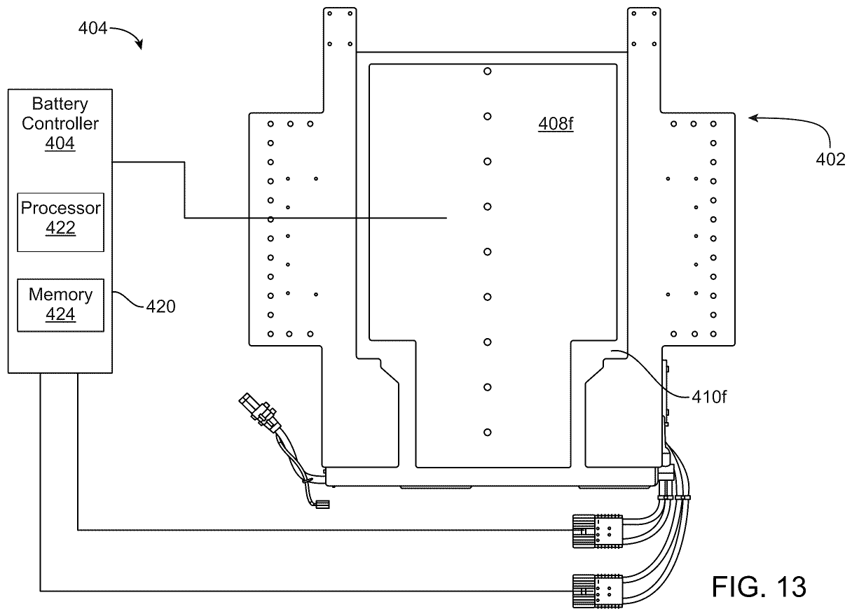

FIGS. 11-13 illustrate a battery temperature management system 400 for heating a battery pack 402. The battery temperature management system 400 includes a battery controller 404 and a plurality of heating pads 408a-g that are positioned on the outside of a housing 406 of the battery pack 402 and electrically connected to the battery controller 404. Heating pad 408g is not shown, but it is positioned on the left side of the housing 406, opposite the heating pad 408c, which is on the right side of the housing 406. In some forms, the heating pad 408g substantially mirrors the shape and placement of the heating pad 408c.

The housing 406 can be provided in the form of a polyhedron, and it has a plurality of outer surfaces 410a-g (e.g., back, top, right, upper front, lower front, bottom, and left). In some forms, the housing 406 is provided in the form of an irregular polyhedron that is a composite of a plurality polyhedrons such as one or more rectangular prisms, one or more truncated rectangular prisms, one or more pentagonal prisms, one or more truncated trapezoidal prisms, and/or one or more other polyhedrons. Each heating pad 408a-g is affixed to and is in thermally conductive contact with one or more of the outer surfaces 410a-g. Further, each heating pad 408a-g is sized and shaped to correspond with the area of the one or more surfaces 410a-g to which the heating pad 408a-g is affixed. The housing 406 supports and contains battery modules (not shown) that are arranged within the housing 406 and electrically coupled to one another to provide electrical power.

The battery controller 404 includes a housing 420 that contains a processor 422 and a memory 424. In some embodiments, the processor 422 and the memory 424 are retained within and protected by the housing 420. Additionally, the processor 422 is communicatively coupled with the memory 424 and is configured to retrieve information from the memory 424.

In one embodiment, each heating pad 408a-g includes its own thermostat that senses the temperature of the heating pad 408a-g and activates and deactivates each of the respective heating pads 408a-g according to a temperature set point that is set locally at each of the heating pads 408a-g. In some forms, the battery controller 404 is configured to set the individual temperature set points for each of the heating pads 408a-g, and each of the heating pads 408a-g includes a temperature sensor and is configured to activate and deactivate itself based on the temperature set points communicated from the battery controller 404. Each of the heating pads 408a-g can be set to different temperature set points from one another to provide even heating and effect specific heat transfer gradients within the battery pack 402 in light of the irregular shape of the housing 420 and the location of the battery modules within the housing 420.

In some embodiments, the battery controller 404 is configured to set the individual temperature set points for each of the heating pads 408a-g and control the activation and deactivation of each of the heating pads 408a-g individually. For example, the battery pack 402 and/or the battery modules can include one or more temperature sensors positioned in various locations within the housing 406. For example, one or more temperature sensors can be associated with each of the surfaces 410a-g and/or attached to each of the surfaces 410a-g, one or more temperature sensors can be positioned centrally within the housing 406 or segments of the housing 406, one or more temperature sensors can be positioned near or in the corners of the housing 406, one or more temperature sensors can be positioned centrally with respect to various parallel strings of battery modules within the housing 406, among other configurations. Accordingly, the temperature sensors can provide localized temperature information with respect to the inside of the housing 406 such that concentrations of high or low temperatures can be readily determined. Further, the temperature sensors can provide sensed temperature information to the battery controller 404 so that the battery controller 404 can individually activate and reactivate each of the heating pads 408a-g to mitigate any temperature concentrations and/or effect specific heat transfer gradients.

More particularly, the battery controller 404 can selectively request that one or more of the heating pads 408a-g be individually powered based on the battery temperature information. For example, the memory 424 can store one or more temperature threshold values corresponding to the one or more temperature sensors. In some forms, the temperature threshold value is the same for every temperature sensor within the housing 406. In some forms, a first temperature threshold value corresponds to some of the temperature sensors, while a second temperature threshold value corresponds to the remaining temperature sensors. In some forms, each temperature sensor is provided with an individually set temperature threshold value.

In some forms, each temperature threshold includes a cut-in temperature value, such as 10° C., below which various heating pads 408a-g will be activated, and a cut-out temperature value, such as 20° C., above which various heating pads 408a-g will be deactivated. Which heating pad 408a-g is activated and when can be determined by the battery controller 404 based on the location of the temperature sensor in the housing 406 that detects a temperature that drops below a set temperature threshold value. In particular, the heating pads 408a-g nearest the temperature sensor that detects a drop in temperature below the temperature threshold value set for that sensor can be activated to locally control the temperature in the housing 406 until the temperature sensor detects that the temperature has risen back above the temperature threshold value.

In some embodiments, the temperature threshold values are also paired with a threshold period time, an activation time, or a reactivation delay time. For example, once the sensed temperature surpasses the temperature threshold for a predetermined period of time, such as 10 seconds, the battery controller 404 can selectively modify its instructions to power the heating pads 408a-g. Further, the battery controller 404 may then selectively power one or more of the heating pads 408a-g for a predetermined time, such as one minute. Even further, any time a heating pad 408a-g is deactivated, the battery controller 404 can implement a reactivation delay time, such that the heating pads 408a-g cannot be reactivated for a period of time after being deactivated to prevent rapid cycling. In operation, the heating pads 408a-g draw power from either the battery modules or another power source to provide heat energy directly from the heating pads 408a-g into the battery pack 402. In some forms, the heating pads 408a-g can draw various amounts of power to heat the battery pack 402 at different rates.

Activating the heating pads 408a-g to reach individual temperature set points and/or to cause various temperature sensors in the housing 406 to stay above various temperature threshold values can help maintain an evenly distributed temperature within the housing 406. Maintaining the internal temperature of the battery pack 402 within the desired range may extend the service life and improve the performance of the battery pack 402.

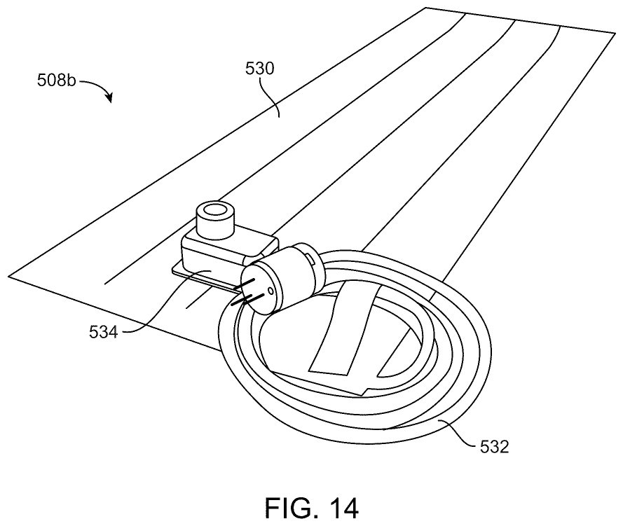

FIG. 14 illustrates an exemplary heating pad 508b, which is representative of one embodiment of a type of heating pad used for the heating pads 408a-g, such as 408b. The heating pad 508b includes a flexible mat 530 with one or more embedded heating elements, a power cable 532, and a power adjuster 534. The power adjuster 534 is in electrical communication with the power cable 532 and the embedded heating elements. The power adjuster 534 modulates energy input from the power cable 532 to the embedded heating elements. In some forms, the power adjuster 534 includes a thermostat with a temperature sensor. Accordingly, the heating pad 508b can be self-regulating based on one or more temperature set points that are set using the power adjuster 534 and/or the battery controller 404. In some forms, the power adjuster 534 is in electrical communication with the battery controller 404 and controlled accordingly, as described above with respect to the heating pads 408a-g.

It should be understood that the battery temperature management system 100, the power unit 302, and the battery temperature management system 400 can all be implemented together in one battery electric vehicle with respect to the battery pack of that vehicle. Further, it is understood that the battery controller 126 and its functions, the controller 320 and its functions, and the battery controller 404 and its functions can all be provided as a part of an integrated battery controller configured to control the functions of the battery temperature management system 100, the power unit 302, and the battery temperature management system 400. Accordingly, each of the temperature control schemes can work in conjunction with one another to control the temperature of the battery pack of a battery electric vehicle.

In other embodiments, other configurations are possible. For example, those of skill in the art will recognize, according to the principles and concepts disclosed herein, that various combinations, sub-combinations, and substitutions of the components discussed above can provide appropriate heating, cooling, and charging for a variety of different configurations of motors, pumps, electronic assemblies, and so on, under a variety of operating conditions.

What is claimed is:

1. A battery temperature management system, comprising:
a drive unit including a motor; and
a power unit including a battery pack, a resistor, and a processor configured to direct regenerative braking current from the motor to the resistor to heat the battery pack based on a motor current value and a battery pack state of charge value.

2. The battery temperature management system of claim 1, wherein the processor selectively directs the regenerative braking current via a switch.

3. The battery temperature management system of claim 1, wherein the resistor is configured as a resistive heating element such that when the regenerative braking current is delivered to the resistor, the battery pack is heated.

4. The battery temperature management system of claim 1, wherein the resistor is positioned substantially adjacent to the battery pack.

5. The battery temperature management system of claim 1, wherein, the resistor is positioned within the battery pack.

6. The battery temperature management system of claim 1, wherein the processor is further configured to direct the regenerative braking current from the motor to the resistor to heat the battery pack based on a battery pack temperature value.

7. The battery temperature management system of claim 6, wherein the battery pack includes a temperature sensor in communication with the processor, and the processor determines the battery pack temperature value based on signals from the temperature sensor.

8. The battery temperature management system of claim 6, wherein when the battery pack state of charge value exceeds a threshold state of charge value, the battery pack temperature value is below a threshold temperature value, and the motor current value is below zero, the processor directs the regenerative braking current to the resistor.

9. The battery temperature management system of claim 6, wherein when the battery pack temperature value exceeds a threshold temperature value, the processor directs the regenerative braking current to the battery pack.

10. The battery temperature management system of claim 1, wherein the battery pack includes a charge sensor in communication with the processor, and the processor determines the battery pack state of charge value based on signals from the charge sensor.

11. The battery temperature management system of claim 1, wherein a motor current sensor is in electrical communication with the motor and the processor, and the processor determines the motor current value based on signals from the motor current sensor.

12. The battery temperature management system of claim 1, wherein the resistor is spaced apart from the battery pack such that heat escaping as waste heat does not substantially impact a temperature of the battery pack.

13. The battery temperature management system of claim 1, wherein when the battery pack state of charge value is below a threshold state of charge value, the processor directs the regenerative braking current to the battery pack.

14. The battery temperature management system of claim 1, wherein one or more of the battery pack and the resistor are in communication with a ground.

15. A battery temperature management system, comprising:
a battery pack and a resistor in communication with a controller, the controller being configured to direct regenerative braking current from a motor to the resistor to warm the battery pack based on a motor current value and a battery pack state of charge value.

16. The battery temperature management system of claim 15, wherein the controller includes an onboard interface and is programmable via the onboard interface.

17. The battery temperature management system of claim 15, wherein when the motor current value is negative and the battery pack state of charge value exceeds a threshold state of charge value, the controller directs the regenerative braking current to the resistor.

18. The battery temperature management system of claim 15, wherein the resistor is configured as a resistive heating element supported by the battery pack.

19. A method for operating a power unit, comprising:
determining a motor current value of a motor;
determining a battery state of charge value of a battery pack; and
directing regenerative braking current from the motor to a resistor to heat the battery pack based on the motor current value and the battery state of charge value.

20. The method of claim 19, wherein the resistor is configured as a resistive heating element such that when the regenerative braking current is delivered to the resistor, the battery pack is heated.
